(19) United States
(12) Patent Application Publication
(10) Pub. No.: US 2004/0175908 A1
(43) Pub. Date: Sep. 9, 2004

(54) Method for manufacturing semiconductor device having gate electrode

(75) Inventors: Yoshiaki Ikematsu, Hyogo (JP); Takashi Terauchi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/689,602

(22) Filed: Oct. 22, 2003

(30) Foreign Application Priority Data
Mar. 6, 2003 (JP) 2003-059562

(51) Int. Cl. H01L 21/3205

(52) U.S. Cl. 438/592

(57) ABSTRACT

A gate insulating film is formed on a substrate, and electrode-constituting films 3, 4, 5, and 6 for constituting a gate electrode are sequentially formed. A silicon nitride film and a second polysilicon film are formed on the metal film, and a resist pattern is formed on the metal film. The second polysilicon film is patterned using the resist pattern as a mask, and the silicon nitride film and the electrode-constituting films are patterned using a patterned second polysilicon film as a mask. An interlayer insulating film is formed on the entire surface of the substrate, and contact holes are formed in the interlayer insulating film. After forming a polysilicon film in the contact holes, polysilicon plugs are formed by CMP using the silicon nitride film as a stopper film.

### BACKGROUND OF THE INVENTION

1. Field of the Invention

The present invention relates to a method for manufacturing a semiconductor device, and more specifically to a method for forming a gate electrode.

2. Description of the Background Art

FIGS. 4A to 4D are sectional views for showing a conventional method for manufacturing a semiconductor device. Specifically, FIGS. 4A to 4D are sectional views showing a method for manufacturing a semiconductor device having a gate electrode.

First, as shown in FIG. 4A, a gate insulating film 2 is formed on a silicon substrate 1. Then, a polysilicon film 3, a metal nitride film (barrier metal film) 4, a metal silicide film 5, a metal film 6, and a silicon nitride film 7 are sequentially formed. Furthermore, a resist pattern 9 is formed using a photolithography technique on the silicon nitride film 7.

Next, as shown in FIG. 4B, the silicon nitride film 7 is patterned by etching using the resist pattern 9 as a mask. Then, the resist pattern 9 is removed.

Next, as shown in FIG. 4C, the metal film 6, the metal silicide film 5, the barrier metal film 4, and the polysilicon film 3 are patterned by etching using the silicon nitride film 7 as a mask.

Finally, as shown in FIG. 4D, a silicon nitride film is formed on the entire surface of the silicon substrate 1, and the silicon nitride film is anisotropically etched to form sidewalls 14 on the sides of gate electrodes.

In recent years, the miniaturization of a gate electrode has increasingly been progressed with the higher integration of semiconductor elements, and the minimum-processing dimension is shifting from 0.13 μm to 0.10 μm, further to less than 0.10 μm. Accompanying the miniaturization of a gate electrode, exposure techniques have been advanced, and the resist suited to the light source of exposure has also been developed.

However, some resists in the initial stage of development had low etching resistance and poor resolution. When such resists were used, there was a problem that the shoulders of a resist pattern 9 were rounded during the etching of the silicon nitride film 7, thus, there were problems that the shoulder rounding of the silicon nitride film 7 occurred and the gate electrodes after etching had a roughened shape. There was also a problem of the breaking of the gate electrodes.

Therefore, conventional manufacturing method had a problem that fine gate electrodes of a high accuracy could not be formed, and the reliability of gate wirings was low.

### SUMMARY OF THE INVENTION

The present invention has been conceived to solve the previously-mentioned problems and a general object of the present invention is to provide a novel and useful method of manufacturing a semiconductor device.

One more specific object of the present invention is to form a fine gate electrode at a high accuracy. Another more specific object of the present invention is to improve the reliability of gate wirings.

The above object of the present invention is attained by a following method of manufacturing a semiconductor device.

According to one aspect of the present invention, in the method for manufacturing a semiconductor device having a gate electrode, a gate insulating film is first formed on a substrate. An electrode-constituting film for constituting the gate electrode is formed on the gate insulating film. A silicon nitride film is formed on the electrode-constituting film. A mask film is formed on the silicon nitride film. A resist pattern is formed on the mask film. The mask film is patterning using the resist pattern as a mask. The silicon nitride film and the electrode-constituting film are, patterning by dry etching using a patterned mask film as a mask. The mask film is removed by CMP using the silicon nitride film as a stopper film after patterning the electrode-constituting film.

According to another aspect of the present invention, in the method for manufacturing a semiconductor device having a gate electrode, a gate insulating film is first formed on a substrate. An electrode-constituting film for constituting the gate electrode is formed on the gate insulating film. A silicon nitride film is formed on the electrode-constituting film. A mask film is formed using the same material as the material of the electrode-constituting film on the silicon nitride film. A resist pattern is formed on the mask film. The mask film is patterned using the resist pattern as a mask. The silicon nitride film and the electrode-constituting film is patterned and simultaneously the mask film is removed, by dry etching using a patterned mask film as a mask.

Other objects and further features of the present invention will be apparent from the following detailed description when read in conjunction with the accompanying drawings.

### BRIEF DESCRIPTION OF THE DRAWINGS

FIGS. 1A to 1I are sectional views for illustrating the method for manufacturing a semiconductor device according to the first embodiment of the present invention;

FIGS. 2A to 2D are sectional views for illustrating the method for manufacturing a semiconductor device according to the second embodiment of the present invention;

FIGS. 3A to 3F are sectional views for illustrating the method for manufacturing a semiconductor device according to the third embodiment of the present invention; and

FIGS. 4A to 4D are sectional views for showing a conventional method for manufacturing a semiconductor device.

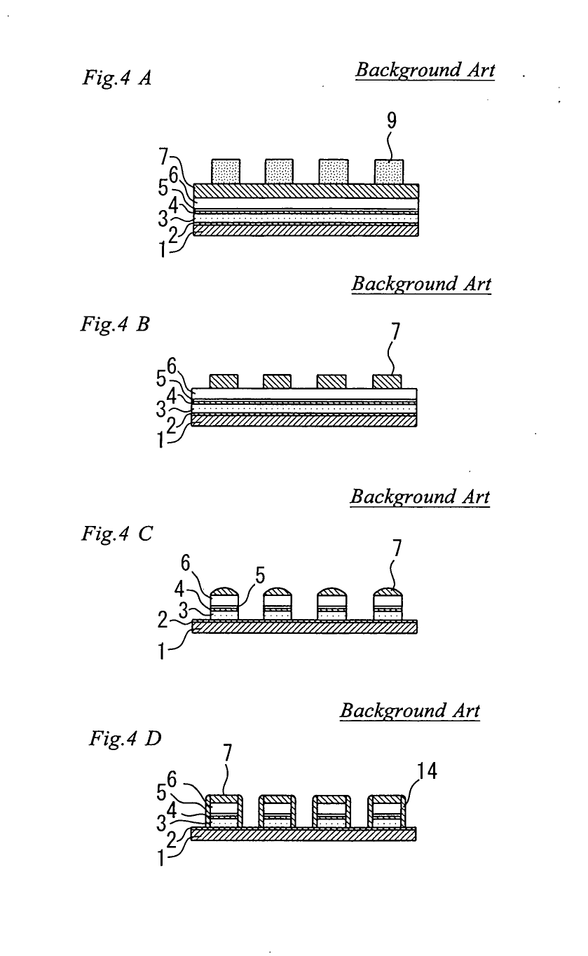

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

First Embodiment

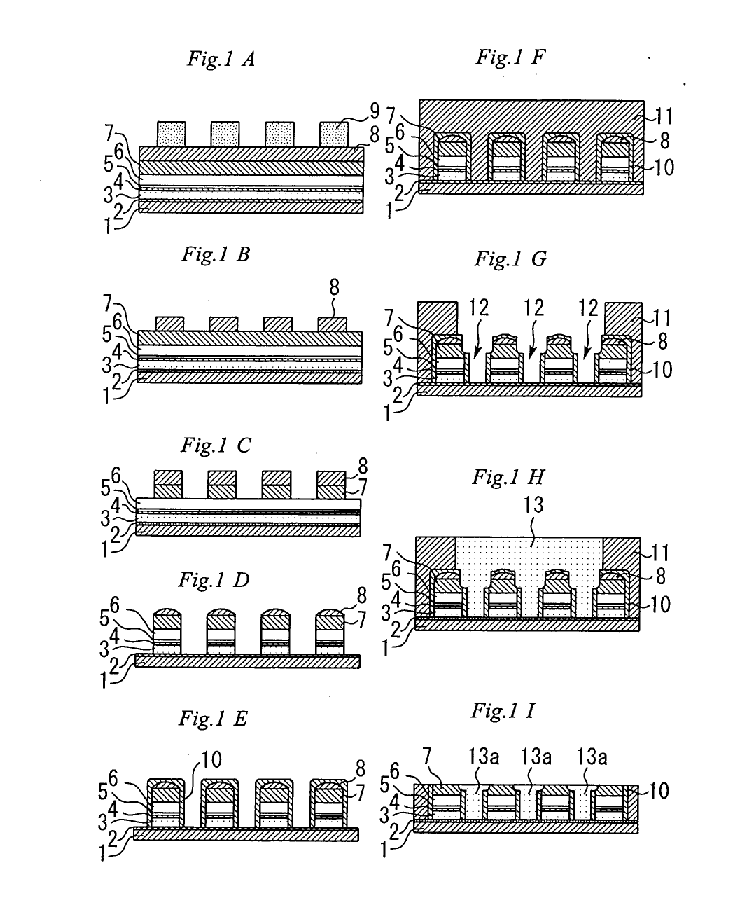

FIGS. 1A to 1I are sectional views for illustrating the method for manufacturing a semiconductor device according to the first embodiment of the present invention. Specifically, FIGS. 1A to 1I are diagrams showing the method for manufacturing a semiconductor device having gate electrodes.

First, as shown in FIG. 1A, a gate oxide film serving as a gate insulating film 2 is formed on a silicon substrate 1. Next, a first polysilicon film 3, a high-melting-point metal nitride film 4, a high-melting-point metal silicide film 5, and a high-melting-point metal film 6 are sequentially formed as electrode-constituting films constituting gate electrodes on the gate insulating film 2. Then a silicon nitride film 7 for insulating the gate electrodes from the upper-layer wirings (not shown) are formed on the high-melting-point metal film 6. Then a second polysilicon film is formed as a mask film 8 on the silicon nitride film 7. Furthermore, a resist pattern 9 is formed using a photolithography technique on the second polysilicon film 8.

Here, the mask film 8 is preferably made of the same material as the material for either one of the electrode-constituting films 3, 4, 5, and 6. The high-melting-point metal nitride film 4 is a barrier metal film such as a tantalum nitride (TaN) film and a titanium nitride (TiN) film. The high-melting-point metal silicide film 5 is, for example, a tungsten silicide (WSi₂) film, a molybdenum silicide (MoSi₂) film, a tantalum silicide (TaSi₂) film, or a titanium silicide (TiSi₂) film. The high-melting-point metal film 6 is, for example, a tungsten (W) film, a molybdenum (Mo) film, a tantalum (Ta) film, a titanium (Ti) film, or an aluminum (Al) film.

Next, as shown in FIG. 1B, the second polysilicon film 8 is patterned by etching using the resist pattern 9 as a mask. Then, the resist pattern 9 is removed.

Next, as shown in FIG. 1C, the silicon nitride film 7 is patterned by etching using a pattern of the second polysilicon film 8 as a mask.

Next, as shown in FIG. 1D, the high-melting-point metal film 6, the high-melting-point metal silicide film 5, the high-melting-point metal nitride film 4, and the first polysilicon film 3 is patterned by etching using the pattern of the second polysilicon film 8 as a mask. Specifically, the electrode-constituting films 6, 5, 4, and 3 are patterned using the patterned second polysilicon film 8 as a mask.

Next, as shown in FIG. 1E, leaving the second polysilicon film 8, a silicon nitride film 10 is formed on the entire surface of the substrate 1, and the silicon nitride film 10 is anisotropically etched to form sidewalls 10 that cover at least the sidewalls of the electrode-constituting films (3, 4, 5, 6).

Next, as shown in FIG. 1F, a silicon oxide film as an interlayer insulating film 11 is formed on the entire surface of the substrate 1.

Next, as shown in FIG. 1G, contact holes 12 are formed in the silicon oxide film 11 using an SAC (self align contact) method.

Next, as shown in FIG. 1H, a polysilicon film serving as a conductive film 13 is formed on the entire surface of the substrate 1 including in the contact holes 12. Here, the conductive film 13 is formed on the same material as the material of the mask film 8. Thereby, the polysilicon film 13 is buried in the contact holes 12.

Next, as shown in FIG. 1I, the polysilicon film 13 is planarized by a CMP (chemical mechanical polishing) using the silicon nitride film 7 as a stopper film. Thereby, the unnecessary polysilicon film 13 and silicon oxide film 11 are removed together with the second polysilicon film 8, and polysilicon plugs serving as contact plugs 13a are formed between gate wirings.

Thereafter, wirings (not shown) are formed on the silicon nitride films 7.

In the first embodiment, as described above, a silicon nitride film 7 and a polysilicon film 8 were formed on the electrode-constituting films (3,4,5,6). Then the polysilicon film 8 was patterned by etching using a resist pattern 9 as a mask, and the silicon nitride film 7 and the electrode-constituting films (3, 4, 5, 6) were patterned by etching using the pattern of the polysilicon film 8 as a mask. Then, the polysilicon film 8 was removed by CMP using the silicon nitride film 7 as a stopper film.

According to the first embodiment, even if the etching resistance of the resist pattern 9 is low, the shoulder rounding of the silicon nitride film 7 can be prevented by forming the polysilicon film as a mask film 8 on the silicon nitride film 7, and a gate-electrode structure with little roughness can be obtained. The breaking of the gate electrodes can also be prevented. Furthermore, the insulation of the wirings on the silicon nitride film 7 from the gate electrodes can be secured. Therefore, fine gate electrodes can be formed at a high accuracy, and the reliability of the gate wirings can be improved.

Furthermore, in the first embodiment the same material as the material of the contact plugs 13a was used as the material for the mask film 8. Specifically, the material for both the mask film 8 and the contact plugs 13a is polysilicon. Thereby, when the unnecessary part of the conductive film 13 and mask film 8 are removed by CMP, the selected ratio can be elevated.

Although polysilicon plugs are formed as the contact plugs 13a in the first embodiment, tungsten plugs may also be formed. In this case, by forming a tungsten film as the mask film 8, the sufficient selected ratio in CMP can be obtained.

Although the second polysilicon film is formed as the mask film 8 in the first embodiment, the present invention is not limited thereto, but a high-melting-point metal nitride film, a high-melting-point metal silicide film, or a high-melting-point metal film may be formed.

Although gate electrodes formed by laminating a first polysilicon film 3, a high-melting-point metal nitride film 4, a high-melting-point metal silicide film 5, and a high-melting-point metal film 6 is described in the first embodiment, the present invention is not limited thereto, but the structure of gate electrodes may be changed appropriately. For example, there may be no need to form the high-melting-point metal nitride film 4 or the high-melting-point metal silicide film 5, depending on the characteristics of the gate electrodes. (This also applies to the second and third embodiments described later.)

Second Embodiment

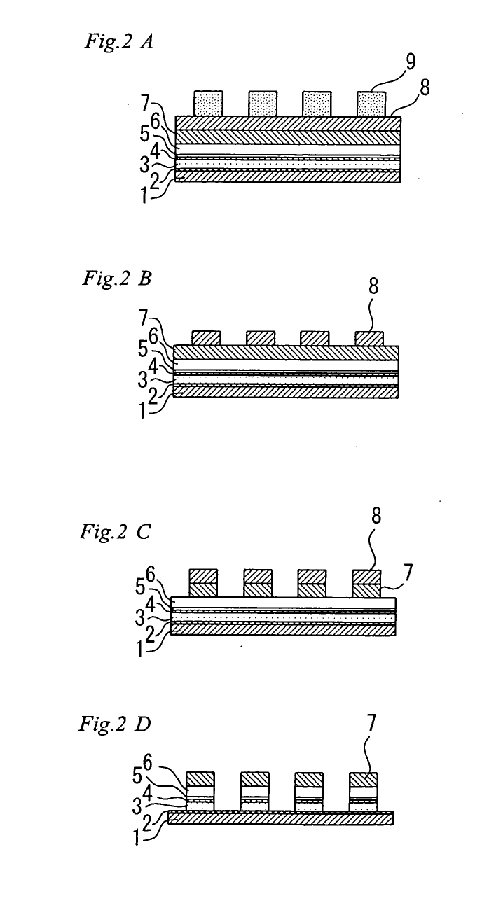

FIGS. 2A to 2D are sectional views for illustrating the method for manufacturing a semiconductor device according to the second embodiment of the present invention. Specifically, FIGS. 2A to 2D are sectional views showing the method for manufacturing a semiconductor device having gate electrodes.

As shown in FIGS. 2A to 2C, the same steps as shown in FIGS. 1A to 1C described in the first embodiment are performed.

Then, as shown in FIG. 2D, the high-melting-point metal film 6, the high-melting-point metal silicide film 5, the high-melting-point metal nitride film 4, and the first polysilicon film 3, which are the electrode-constituting films, are patterned by etching using the pattern of the second polysilicon film 8 as a mask. Here, by controlling the etching time, the second polysilicon film 8 is removed at the same time that the electrode-constituting films (6, 5, 4, 3) are patterned.

Thereafter, wirings (not shown) are formed on the silicon nitride films 7.

In the second embodiment, as described above, a silicon nitride film 7 and a polysilicon film 8 were formed on the electrode-constituting films (3, 4, 5, 6), the polysilicon film 8 was patterned by etching using a resist pattern as a mask, and the silicon nitride film 7 and the electrode-constituting films (3, 4, 5, 6) were patterned by etching using the pattern of the polysilicon film 8 as a mask. Here, the polysilicon film 8 was removed by controlling the etching time when the electrode-constituting films (3, 4, 5, 6) were patterned.

Therefore, even if the etching resistance of the resist pattern 9 is low, the shoulder rounding of the silicon nitride film 7, which occurs when a conventional manufacturing method is used, can be prevented by forming the polysilicon film as a mask film 8 on the silicon nitride film 7, and a gate-electrode structure with little roughness can be obtained. The breaking of the gate electrodes can also be prevented. Furthermore, the insulation of the wirings on the silicon nitride film 7 from the gate electrodes can be secured. Therefore, fine gate electrodes can be formed at a high accuracy, and the reliability of the gate wirings can be improved.

Although a second polysilicon film is formed as the mask film 8 in the second embodiment, the present invention is not limited thereto, but a high-melting-point metal nitride film, a high-melting-point metal silicide film, or a high-melting-point metal film may be formed. In this case also, the patterning of the silicon nitride film 7 and the electrode-constituting films (3, 4, 5, 6), and the removal of the mask film 8 can be performed simultaneously.

Third Embodiment

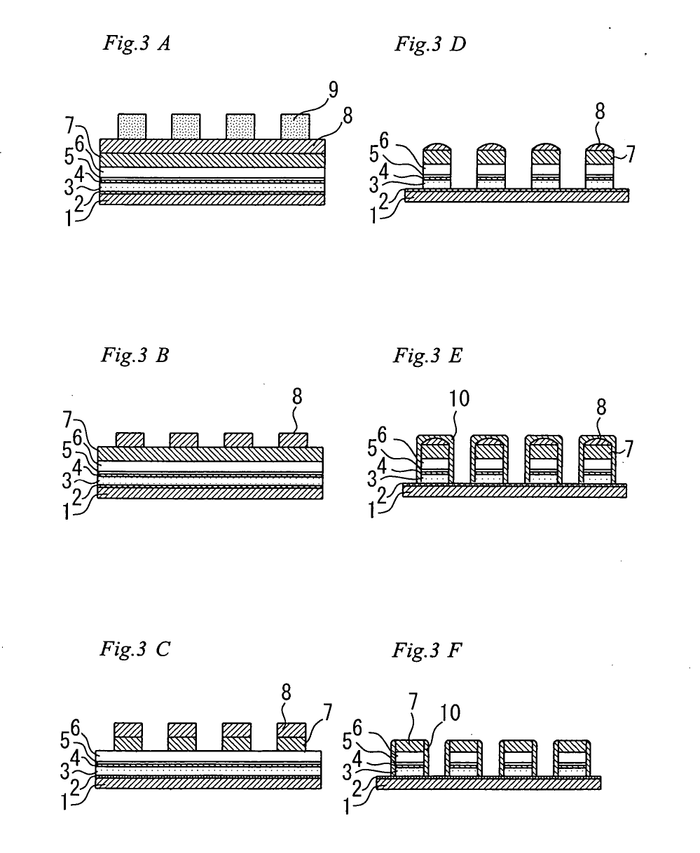

FIGS. 3A to 3F are sectional views for illustrating the method for manufacturing a semiconductor device according to the third embodiment of the present invention. Specifically, FIGS. 3A to 3F are sectional views showing the method for manufacturing a semiconductor device having gate electrodes.

As shown in FIGS. 3A to 3E, the same steps as shown in FIGS. 1A to 1E described in the first embodiment are performed.

Next, as shown in FIG. 3F, the second polysilicon film 8 formed on the silicon nitride film 7 is removed by CMP using the silicon nitride film 7 as the stopper film. By this CMP, the silicon nitride film 10 formed on the second polysilicon film 8 when the sidewalls are formed (refer to FIG. 3E) is also removed.

Thereafter, wirings (not shown) are formed on the silicon nitride films 7.

In the third embodiment, as described above, a silicon nitride film 7 and a polysilicon film 8 were formed on the electrode-constituting films (3, 4, 5, 6), and the silicon nitride film 7 and the electrode-constituting films (3, 4, 5, 6) were patterned by etching using the resist pattern 9 as a mask. Then, sidewalls 10 were formed on the sidewalls of the electrode-constituting films, and the polysilicon film 8 was removed by CMP using the silicon nitride film 7 as the stopper film.

Therefore, even if the etching resistance of the resist pattern 9 is low, the shoulder rounding of the silicon nitride film 7, which occurs when a conventional manufacturing method is used, can be prevented by forming the polysilicon film as a mask film 8 on the silicon nitride film 7, and a gate-electrode structure with little roughness can be obtained. The breaking of the gate electrodes can also be prevented. Furthermore, the insulation of the wirings on the silicon nitride film 7 from the gate electrodes can be secured. Therefore, fine gate electrodes can be formed at a high accuracy, and the reliability of the gate wirings can be improved.

This invention, when practiced illustratively in the manner described above, provides the following major effects:

According to the present invention, fine gate electrodes can be formed at a high accuracy, and the reliability of the gate wirings can be improved.

Further the present invention is not limited to these embodiments, but variations and modifications may be made without departing from the scope of the present invention.

The entire disclosure of Japanese Patent Application No. 2003-059562 filed on Mar. 6, 2003 containing specification, claims, drawings and summary are incorporated herein by reference in its entirety.

What is claimed is:

1. A method for manufacturing a semiconductor device having a gate electrode comprising the steps of:
forming a gate insulating film on a substrate;
forming an electrode-constituting film for constituting the gate electrode on the gate insulating film,
forming a silicon nitride film on the electrode-constituting film;
forming a mask film on the silicon nitride film;
forming a resist pattern on the mask film;
patterning the mask film using the resist pattern as a mask;
patterning the silicon nitride film and the electrode-constituting film by dry etching using a patterned mask film as a mask; and
removing the mask film by CMP using the silicon nitride film as a stopper film after patterning the electrode-constituting film.

2. The method for manufacturing a semiconductor device according to claim 1 further comprising the steps of:
forming an interlayer insulating film after patterning the electrode-constituting film;
forming contact holes in the interlayer insulating film; and
forming a conductive film on the entire surface of the substrate including in the contact holes,
wherein contact plugs are formed in the interlayer insulating film, and the mask film is simultaneously removed in said step of removing the mask film by CMP using the silicon nitride film as a stopper film.

3. The method for manufacturing a semiconductor device according to claim 2, wherein the material of the mask film is the same as the material of the contact plugs.

4. The method for manufacturing a semiconductor device according to claim 1, further comprising the step of forming wirings on the silicon nitride film after removing the mask film.

5. A method for manufacturing a semiconductor device having a gate electrode comprising the steps of:
forming a gate insulating film on a substrate;
forming an electrode-constituting film for constituting the gate electrode on the gate insulating film;
forming a silicon nitride film on the electrode-constituting film;
forming a mask film using the same material as the material of the electrode-constituting film on the silicon nitride film;
forming a resist pattern on the mask film;
patterning the mask film using the resist pattern as a mask; and
patterning the silicon nitride film and the electrode-constituting film, and simultaneously removing the mask film, by dry etching using a patterned mask film as a mask.

6. The method for manufacturing a semiconductor device according to claim 5, further comprising a step for forming wirings on the patterned silicon nitride film.
